(19) United States
(12) Patent Application Publication
(10) Pub. No.: US 2015/0233017 A1
(43) Pub. Date: Aug. 20, 2015

(54) VAPOR PHASE GROWTH METHOD

(71) Applicant: NuFlare Technology, Inc., Kanagawa (JP)

(72) Inventors: Takumi YAMADA, Kanagawa (JP); Yuusuke SATO, Tokyo (JP)

(21) Appl. No.: 14/624,068

(22) Filed: Feb. 17, 2015

(30) Foreign Application Priority Data
Feb. 20, 2014 (JP) 2014-030324

(51) Int. Cl. C30B 25/18; C30B 29/40

(52) U.S. Cl. CPC C30B 25/183; C30B 29/403; C30B 29/406

(57) ABSTRACT

A vapor phase growth method according to embodiments uses a vapor phase growth apparatus including a reaction chamber, a transfer chamber, and a standby chamber. After a film containing gallium (Ga) is formed on a first substrate, a deposit adhering to a support is covered with a coating film or is removed. After that, an aluminum nitride film is formed successively on a plurality of substrates having a silicon (Si) surface, and the substrates are transferred into the standby chamber. Then, the substrates are transferred sequentially from the standby chamber into the reaction chamber, such that a film containing gallium (Ga) is formed successively on the substrates.

### CROSS-REFERENCE TO RELATED APPLICATION

This application is based upon and claims the benefit of priority from Japanese Patent Applications No. 2014-030324, filed on Feb. 20, 2014, the entire contents of which are incorporated herein by reference.

### FIELD OF THE INVENTION

Embodiments of the present invention relate to vapor phase growth methods for forming films with the supply of gas.

### BACKGROUND OF THE INVENTION

One of the methods for forming high-quality semiconductor films is an epitaxial growth technology. The epitaxial growth technology is a method to grow a single-crystal film by vapor phase epitaxy on a substrate such as a wafer. In a vapor phase epitaxy apparatus for use in the epitaxial growth technology, a wafer is placed on a support in a reaction chamber that is maintained at an atmospheric pressure or in a reduced pressure. Then, a process gas such as a source gas is supplied onto the surface of the wafer from, for example, a shower plate disposed in an upper portion of the reaction chamber while the wafer is being heated. A thermal reaction of the source gas occurs on the surface of the wafer, such that an epitaxial single-crystal film is formed on the surface of the wafer.

Recently, GaN (gallium nitride) semiconductor devices are drawing attention as a material for luminescent devices or power devices. One of the epitaxial growth technologies for forming GaN semiconductor films is a metal organic chemical vapor deposition method (MOCVD method). In the metal organic chemical vapor deposition method, for example, an organic metal such as trimethylgallium (TMG), trimethylindium (TMI), and trimethylaluminum (TMA), and ammonia (NH₃) are used as a source gas.

In case where a GaN semiconductor film is formed on a Si (silicon) substrate, reaction between Ga and Si hinders growth of a high-quality single-crystal film. JP-A 2009-007205 describes a film forming method wherein a film of AlN (aluminum nitride) is formed on a jig in order to deal with this problem.

Forming an AlN film on a jig each time a GaN semiconductor film is formed may lead to lowering of the throughput in GaN semiconductor film formation.

### SUMMARY OF THE INVENTION

A vapor phase growth method according to one aspect of the present disclosure is a vapor phase growth method using a vapor phase growth apparatus including a reaction chamber, a transfer chamber connected to the reaction chamber, and a standby chamber connected to the transfer chamber. The method includes: transferring a first substrate into the reaction chamber; forming a film containing gallium (Ga) on the first substrate to be placed on a support inside the reaction chamber; transferring the first substrate out of the reaction chamber; covering a deposit with a coating film after the transferring of the first substrate out of the reaction chamber, the deposit adhering to the support; transferring a second substrate into the reaction chamber after the covering of the deposit with the coating film, the second substrate having a silicon (Si) surface; forming an aluminum nitride film on the second substrate; transferring the second substrate from the reaction chamber into the transfer chamber and then into the standby chamber; transferring a third substrate into the reaction chamber, the third substrate having a silicon (Si) surface; forming an aluminum nitride film on the third substrate; transferring the third substrate from the reaction chamber into the transfer chamber and then into the standby chamber; transferring the second substrate from the standby chamber into the transfer chamber and then into the reaction chamber; forming a film containing gallium (Ga) on the second substrate; transferring the second substrate out of the reaction chamber; transferring the third substrate from the standby chamber into the transfer chamber and then into the reaction chamber; forming a film containing gallium (Ga) on the third substrate; and transferring the third substrate out of the reaction chamber.

A vapor phase growth method according to one aspect of the present disclosure is a vapor phase growth method using a vapor phase growth apparatus including a reaction chamber, a transfer chamber connected to the reaction chamber, and a standby chamber connected to the transfer chamber. The method includes: transferring a first substrate into the reaction chamber; forming a film containing gallium (Ga) on the first substrate to be placed on a support inside the reaction chamber; transferring the first substrate out of the reaction chamber; removing a deposit after the transferring of the first substrate out of the reaction chamber, the deposit adhering to the support; transferring a second substrate into the reaction chamber after the removing of the deposit, the second substrate having a silicon (Si) surface; forming an aluminum nitride film on the second substrate; transferring the second substrate from the reaction chamber into the transfer chamber and then into the standby chamber; transferring a third substrate into the reaction chamber, the third substrate having a silicon (Si) surface; forming an aluminum nitride film on the third substrate; transferring the third substrate from the reaction chamber into the transfer chamber and then into the standby chamber; transferring the second substrate from the standby chamber into the transfer chamber and then into the reaction chamber; forming a film containing gallium (Ga) on the second substrate; transferring the second substrate out of the reaction chamber; transferring the third substrate from the standby chamber into the transfer chamber and then into the reaction chamber; forming a film containing gallium (Ga) on the third substrate; and transferring the third substrate out of the reaction chamber.

### BRIEF DESCRIPTION OF THE DRAWINGS

FIG. 1 is a configuration diagram of a vapor phase growth apparatus for use in a vapor phase growth method according to a first embodiment.

FIG. 2 is a schematic cross-sectional view of the vapor phase growth apparatus for use in the vapor phase growth method according to the first embodiment.

FIG. 3 is a process flow diagram of the vapor phase growth method according to the first embodiment.

FIG. 4 is a process flow diagram of a vapor phase growth method according to a second embodiment.

FIG. 5 is a process flow diagram of a vapor phase growth method according to a third embodiment.

FIG. 6 is a configuration diagram of a vapor phase growth apparatus according to a fourth embodiment.

### DETAILED DESCRIPTION OF THE EMBODIMENTS

Embodiments of the present invention are described with reference to the drawings.

It is to be noted herein that the direction of gravity in a state where a vapor phase growth apparatus is set for film formation is defined as “down,” and the direction opposite thereto is defined as “up.” Hence, a “lower portion” means a position in the direction of gravity with respect to a reference, and a “downward/below” means the direction of gravity with respect to the reference. An “upper portion” means a position in the direction opposite the direction of gravity with respect to the reference, and “upward/above” means the direction opposite the direction of gravity with respect to the reference. The “vertical direction” is the direction of gravity.

Further, the “process gas” herein is a generic term for gases for use in forming a film on a substrate and is a concept encompassing, for example, a source gas, a carrier gas, a separation gas, and a compensation gas.

Further, “nitrogen gas” herein is included in “inert gas.”

### First Embodiment

A vapor phase growth method according to the first embodiment is a vapor phase growth method using a vapor phase growth apparatus including a reaction chamber, a transfer chamber connected to the reaction chamber, and a standby chamber connected to the transfer chamber. The method includes: transferring a first substrate into the reaction chamber; forming a film containing gallium (Ga) on the first substrate to be placed on a support inside the reaction chamber; transferring the first substrate out of the reaction chamber; transferring a dummy substrate into the reaction chamber after the transferring of the first substrate out of the reaction chamber; forming an aluminum nitride film on the dummy substrate; transferring the dummy substrate out of the reaction chamber; transferring a second substrate into the reaction chamber after the transferring of the dummy substrate out of the reaction chamber, the second substrate being different from the first substrate and having a silicon (Si) surface; forming an aluminum nitride film on the second substrate; transferring the second substrate from the reaction chamber into the transfer chamber and then into the standby chamber; transferring a third substrate into the reaction chamber, the third substrate having a silicon (Si) surface; forming an aluminum nitride film on the third substrate; transferring the third substrate from the reaction chamber into the transfer chamber and then into the standby chamber; transferring the second substrate from the standby chamber into the transfer chamber and then into the reaction chamber; forming a film containing gallium (Ga) on the second substrate; transferring the second substrate out of the reaction chamber; transferring the third substrate from the standby chamber into the transfer chamber and then into the reaction chamber; forming a film containing gallium (Ga) on the third substrate; and transferring the third substrate out of the reaction chamber.

According to the vapor phase growth method of the first embodiment, an aluminum nitride film is formed successively on a plurality of substrates in the same reaction chamber, and then a film containing gallium (Ga) is formed successively on the same substrates. This allows for reduction of the number of formation of the aluminum nitride film on the dummy substrate after forming the film containing gallium (Ga). Thus, the throughput in forming a GaN semiconductor film is improved.

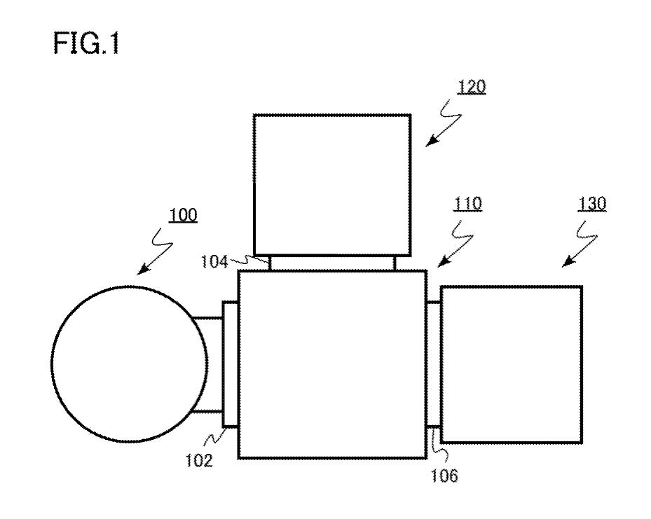

FIG. 1 is a configuration diagram of a vapor phase growth apparatus for use in a vapor phase growth method according to the first embodiment. The vapor phase growth apparatus according to the first embodiment is a vertical, single wafer type epitaxial growth apparatus for use with the MOCVD method (metal organic chemical vapor deposition method).

The vapor phase growth apparatus includes a reaction chamber 100, a transfer chamber 110 connected to the reaction chamber 100, and a standby chamber 120 connected to the transfer chamber 110. The vapor phase growth apparatus further includes a load lock chamber 130 connected to the transfer chamber 110.

Formation of films on substrates is performed in the reaction chamber 100. A substrate prior to or subsequent to film formation is temporarily stored in the standby chamber 120. The load lock chamber 130 is provided for loading and unloading the substrate prior to or subsequent to film formation. The load lock chamber 130 is provided for carrying out a film formation process without releasing the reaction chamber 100 and the standby chamber 120 to the air.

The transfer chamber 110 has a function of transferring a substrate among the reaction chamber 100, the standby chamber 120, and the load lock chamber 130. For example, the transfer chamber 110 is equipped with a conveyor robot, and the conveyor robot conveys the substrate. The conveyor robot has, for example, a handling arm.

A first gate valve 102 is positioned between the transfer chamber 110 and the reaction chamber 100. The first gate valve 102 has a function of separating the atmosphere and pressure between the transfer chamber 110 and the reaction chamber 100.

A second gate valve 104 is positioned between the transfer chamber 110 and the standby chamber 120. The second gate valve 104 has a function of separating the atmosphere and pressure between the transfer chamber 110 and the standby chamber 120.

A third gate valve 106 is positioned between the transfer chamber 110 and the load lock chamber 130. The third gate valve 106 has a function of separating the atmosphere and pressure between the transfer chamber 110 and the load lock chamber 130.

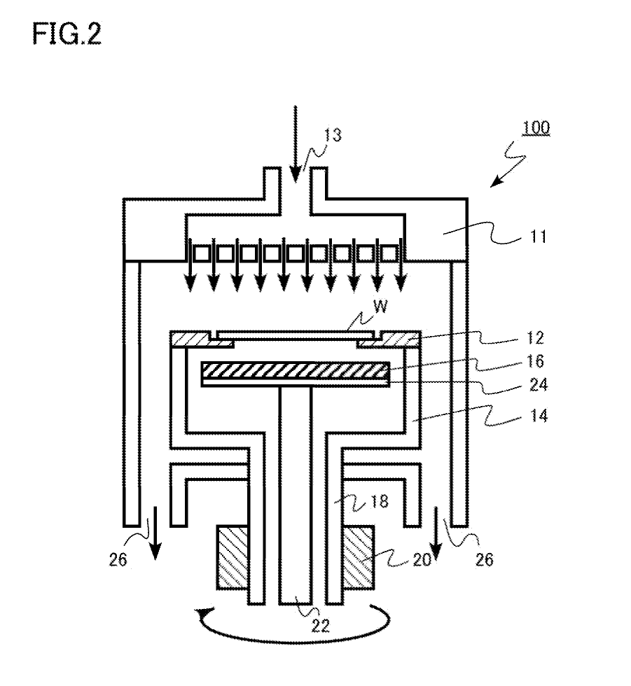

FIG. 2 is a schematic cross-sectional view of the reaction chamber of the vapor phase growth apparatus for use in the vapor phase growth method according to the present embodiment.

The reaction chamber 100 is, for example, made of a cylindrical hollow body of stainless steel. The reaction chamber 100 includes a shower plate 11 that is positioned in an upper portion of the reaction chamber 100 so as to supply the reaction chamber 100 with a process gas. The shower plate 11 has in an upper portion thereof a gas supplier 13 for supplying the reaction chamber 100 with, for example, a process gas or a cleaning gas.

Further, the reaction chamber 100 includes a support 12 that is disposed below the shower plate 11 inside the reaction chamber 100 so as to allow a semiconductor wafer (substrate) W to be placed thereon. The support 12 may be, for example, a ring holder having an opening at a central portion thereof as depicted in FIG. 2. Alternatively, the support 12 may be a susceptor with a structure contacting almost the entire rear surface of the semiconductor wafer W.

Further, the reaction chamber 100 includes a rotor unit 14 that is rotatable with the support 12 mounted on the upper surface thereof. Further, the reaction chamber 100 includes a heater in the form of a heating portion 16 for heating the wafer W placed on the support 12. The heating portion 16 is disposed below the support 12. It is to be noted here that the rotor unit 14 has a rotary shaft 18 connected to a rotational driving mechanism 20 that is positioned below the rotary shaft 18. The rotational driving mechanism 20 is configured to rotate the semiconductor wafer W at several tens of rpm to several thousands of rpm, for example, 300 rpm to 1000 rpm relative to the center of the semiconductor wafer W as the rotation center.

The cylindrical rotor unit 14 desirably has a diameter that is approximately the same as the outer peripheral diameter of the support 12. It is to be noted that the rotary shaft 18 is rotatably disposed on a bottom portion of the reaction chamber 100. A vacuum seal member is provided between the rotary shaft 18 and the reaction chamber 100.

The heating portion 16 is fixedly positioned on a support table 24 that is fixedly attached to a support shaft 22 penetrating the inner portion of the rotary shaft 18. The heating portion 16 is supplied with power from a current introducing terminal and an electrode that are not shown. The support table 24 is provided with, for example, a push up pin (not shown) for detaching the semiconductor wafer W from the ring holder 12.

Moreover, a gas outlet 26 is provided in a bottom portion of the reaction chamber 100 so as to discharge a leftover reaction product after reaction of the source gas on, for example, the surface of the semiconductor wafer W and a residual gas in the reaction chamber 100 to the outside of the reaction chamber 100. The gas outlet 26 is connected to a vacuum pump (not shown).

The single wafer type epitaxial growth apparatus depicted in FIG. 2 has a wafer gateway (not shown) and the first gate valve 102 located in a sidewall of the reaction chamber 100 so as to load and unload the semiconductor wafer. It is configured such that the semiconductor wafer W is transferred by the handling arm between the transfer chamber 110 and the reaction chamber 100 that are connected by the first gate valve 102. The handling arm which is made of, for example, synthetic quartz is insertable into a space between the shower plate 11 and the wafer support 12.

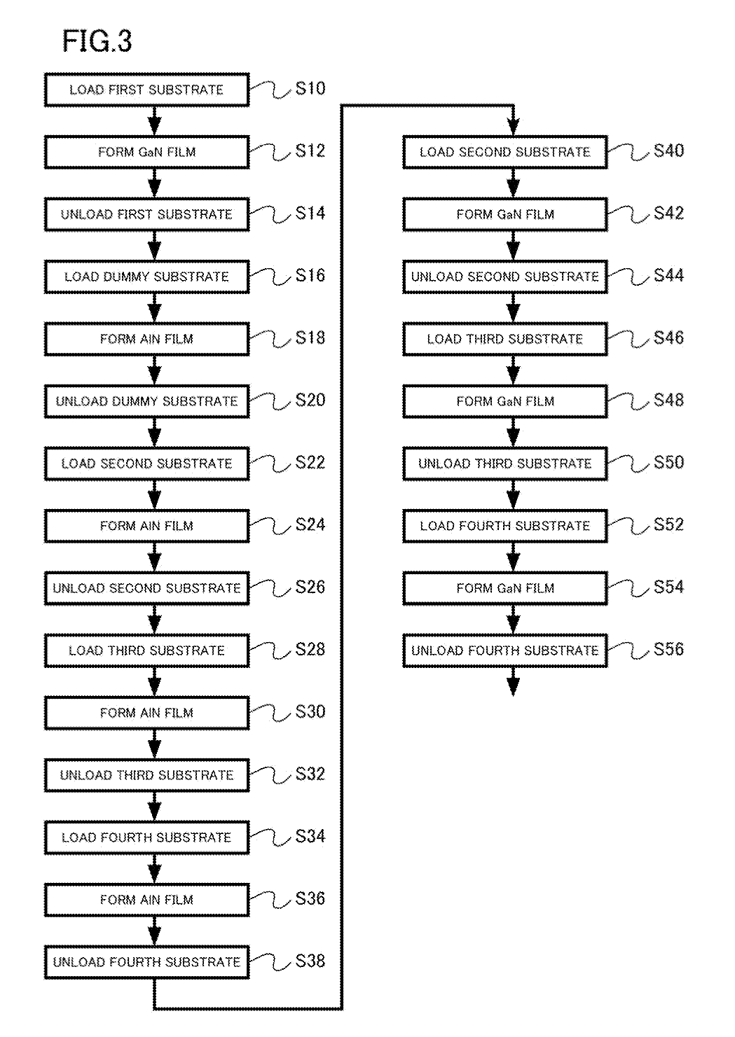

FIG. 3 is a process flow diagram of the vapor phase growth method according to the present embodiment. The vapor phase growth method according to the present embodiment is performed by using the single wafer type epitaxial growth apparatus depicted in FIGS. 1 and 2.

First, a first substrate, such as a first wafer (first substrate) W1 having an AlN (aluminum nitride) film serving as a buffer layer on an Si substrate of a (111) surface, is transferred into the reaction chamber 100 (S10). At this point, for example, the first gate valve 102 at the wafer gateway in the reaction chamber 100 is opened and, for example, the first wafer W1 stored in the standby chamber 120 is transferred into the reaction chamber 100 by the handling arm in the transfer chamber 110.

Then, the first wafer W1 is placed on the support 12, for example, by using the push up pin (not shown). The handling arm is returned to the transfer chamber 110, and the first gate valve 102 is closed.

Then, the vacuum pump (not shown) is actuated to discharge the gas inside the reaction chamber 100 from the gas outlet 26, so as to attain a predetermined degree of vacuum. At this time, the heating power of the heating portion 16 is increased, so as to maintain the first wafer W1 at a preliminary heating temperature. After that, the heating power of the heating portion 16 is increased, so as to raise the temperature of the first wafer W1 to an epitaxial growth temperature, such as a temperature in a range from 1000° C. to 1100° C.

Then, a process gas is supplied from the gas supplier 13 through the shower plate 11 into the reaction chamber 100. This causes a GaN (gallium nitride) film containing gallium (Ga) to be formed by epitaxial growth over the AlN film surface of the first wafer W1 (S12).

The process gas includes a gas containing gallium (Ga). The process gas comprises, for example, a gas of trimethylgallium (TMG) diluted with hydrogen (H₂) gas, and ammonia (NH₃). Trimethylgallium (TMG) is a gas containing gallium (Ga), and ammonia (NH₃) is a gas containing nitrogen (N).

In forming a GaN film on the first wafer W1, a reaction product adheres as a deposit also to some portions of the reaction chamber 100 besides the first wafer W1. Especially, much deposit may adhere to an area, which is uncovered with the wafer, of the support 12 that is set at a high temperature to cause the reaction. The deposit is, for example, GaN.

The film to be formed on the first wafer W1 may be any film besides GaN insofar as the film is formed with the supply of a source gas containing gallium (Ga). The film may be, for example, InGaN (indium gallium nitride) or AlGaN (aluminum gallium nitride) insofar as the film contains Ga.

On completion of epitaxial growth, the supply of the process gas is stopped, and the supplying of the process gas onto the first wafer W1 is stopped, such that the growth of the GaN single-crystal film is terminated.

After the film formation, the temperature of the first wafer W1 begins to lower. The first wafer W1 on which the GaN single-crystal film is formed is left on the support 12 and the heating power of the heating portion 16 is turned back to the initial level, so as to adjust the temperature to be lowered to the preliminary heating temperature.

Once the first wafer W1 is stabilized at a predetermined temperature, the first wafer W1 is detached from the support 12, for example, by the push up pin. Then, the first gate valve 102 is opened again, so as to insert the handling arm in between the shower plate 11 and the support 12. Then, the first wafer W1 is placed on the handling arm. After that, the handling arm mounting the first wafer W1 thereon is returned into the transfer chamber 110, so as to transfer the first wafer W1, which is the first substrate, to the outside of the reaction chamber 100 (S14).

After the first wafer W1 is transferred out of the reaction. chamber 100, a dummy wafer (dummy substrate) Wd is transferred into the reaction chamber 100 (S16). The dummy wafer Wd is, for example, an Si (silicon) wafer.

Subsequently, an AlN (aluminum nitride) film is formed on the surface of the dummy wafer Wd (S18). The AlN film makes a coating film for covering the deposit. The process gas comprises, for example a gas of trimethylaluminum (TMA) diluted with hydrogen (H₂) gas, and ammonia (NH₃). Trimethylgallium (TMA) is a gas containing aluminum (Al), and ammonia (NH_) is a gas containing nitrogen (N).

In forming an AlN film on the surface of the dummy wafer Wd, the deposit is covered with the AlN film, which deposit has adhered to, for example, the support 12 in the reaction chamber 100 during the previous GaN film formation with respect to the first wafer W1. This suppresses dispersion of, for example, Ga from the deposit into the atmosphere of the reaction chamber 100 in subsequent film formation.

After that, the dummy wafer Wd is transferred out of the reaction chamber 100 (S20).

After the dummy wafer Wd is transferred out of the reaction chamber 100, a second wafer (second substrate) W2 having a silicon (Si) surface is transferred into the reaction chamber 100. The second wafer (second substrate) W2 is different from the first wafer (first substrate) W1 (S22). The second wafer W2 is, for example, an Si substrate having a (111) surface. The second wafer W2 is, for example, stored in advance in the standby chamber 120 and is transferred into the reaction chamber 100 in the same manner as with the first wafer W1.

Then, the vacuum pump (not shown) is actuated to discharge the gas inside the reaction chamber 100 from the gas outlet 26, so as to attain a predetermined degree of vacuum. The second wafer W2 placed on the support 12 is preliminarily heated by the heating portion 16 to a predetermined temperature.

Moreover, the heating power of the heating portion 16 is increased to raise the temperature of the second wafer W2 to a predetermined temperature such as a temperature in a range from 1150° C. to 1250° C.

Then, exhaust by means of the vacuum pump is continued, when baking (annealing) prior to film formation is performed with the rotor unit 14 being rotated at an appropriate speed. The baking removes, for example, a native oxide film on the second wafer W2, such that Si becomes exposed on the surface.

In baking, for example, hydrogen gas is supplied through the gas supplier 13 into the reaction chamber 100. Baking is performed for a predetermined period of time, and then, for example, the heating power of the heating portion 16 is reduced, so as to lower the temperature of the second wafer W2 to an epitaxial growth temperature such as a temperature in a range from 1000° C. to 1100° C.

Then, the process gas is supplied from the gas supplier 13 through the shower plate 11 into the reaction chamber 100. In this manner, an AlN (aluminum nitride) film is formed on the Si surface of the second wafer W2 by epitaxial growth (S24).

The process gas comprises, for example, a gas of trimethylaluminum (TMA) diluted with hydrogen (H₂) gas, and ammonia (NH₃). Trimethylaluminum (TMA) is a source gas for aluminum (Al), and ammonia (NH₃) is a source gas for nitrogen (N).

Then, on completion of growth of the AlN single-crystal film, the supply of the process gas from the gas supplier 13 is stopped, and the supplying of the process gas onto the second wafer W2 is stopped, such that the growth of the AlN single-crystal film is terminated.

The second wafer W2 is transferred from the reaction chamber 100 into the transfer chamber 110, and then is transferred into the standby chamber 120 (S26).

After that, a third wafer (third substrate) W3 having a silicon (Si) surface is transferred into the reaction chamber 100 (S28). The third wafer W3 is, for example, stored in the standby chamber 120 in advance.

Then, in the same manner as in the case of the second wafer W2, an AlN film is formed on the surface of the third wafer W3 (S30). After that, in the same manner as in the case of the second wafer W2, the third wafer W3 is transferred from the reaction chamber 100 into the transfer chamber 110, and then is transferred into the standby chamber 120 (S32).

After that, a fourth wafer (fourth substrate) W4 having a silicon (Si) surface is transferred into the reaction chamber 100 (S34). The fourth wafer W4 is, for example, stored in the standby chamber 120 in advance.

Then, in the same manner as in the case of the second wafer W2, an AlN film is formed on the surface of the fourth wafer W4 (S36). After that, in the same manner as in the case of the second wafer W2, the fourth wafer W4 is transferred from the reaction chamber 100 into the transfer chamber 110, and then is transferred into the standby chamber 120 (S38).

In this manner, after the AlN film is formed on the dummy wafer Wd, an AlN film is formed successively on the three wafers W2 to W4. The number of wafers to be subjected to the successive AlN film formation is not limited to three and may be two or not less than four.

The wafers subjected to the successive AlN film formation are transferred into the standby chamber 120 and are temporarily stored therein in a decompressed condition without being released to the air.

After the fourth wafer W4 is transferred out of the reaction chamber 100, one wafer out of the second to fourth wafers W2 to W4 that are stored in the standby chamber 120 is transferred into the reaction chamber 100. Any wafer may be selected at this point, but description is given here of a case in which the second wafer W2 is transferred into the reaction chamber 100 (S40).

Then, a film containing gallium (Ga), for example, a GaN single-crystal film is grown over the AlN film on the second wafer W2 (S42). A process gas for forming the GaN film is supplied from the gas supplier of the shower plate 11. The temperature of the second wafer W2 is, for example, set in a range from 1000° C. to 1100° C.

The process gas includes a source gas containing gallium (Ga). The process gas comprises, for example, a gas of trimethylgallium (TMG) diluted with hydrogen (H₂) gas, and ammonia (NH₃). Trimethylgallium (TMG) is a source gas for gallium (Ga), and ammonia (NH₃) is a source gas for nitrogen (N).

The film to be formed over the AlN film is not limited to GaN. The film may be, for example, InGaN (indium gallium nitride), or AlGaN (aluminum gallium nitride) insofar as the film contains Ga.

On completion of epitaxial growth, the supply of the process gas from the gas supplier is stopped, and the supplying of the process gas onto the second wafer W2 is stopped, such that the growth of the GaN single-crystal film is terminated.

After the film formation, the temperature of the second wafer W2 begins to lower. At this point, for example, the rotor unit 14 is stopped from rotation, and the heating power of the heating portion 16 is turned back to the initial level with the second wafer W2 having the GaN single-crystal film formed thereon left on the support 12, so as to adjust the temperature to be lowered to the preliminary heating temperature.

After that, the second wafer W2 is transferred out of the reaction chamber 100 (S44). Then, the third wafer W3 stored in the standby chamber 120 is transferred into the reaction chamber 100 through the transfer chamber 110 (S46).

Then, in the same manner as with the second wafer W2, a film containing gallium (Ga) such as a GaN single-crystal film is grown over the AlN film on the third wafer W3 (S48). After the film formation, in the same manner as with the second wafer W2, the third wafer W4 is transferred to the outside of the reaction chamber 100 (S50). Then, the fourth wafer W4 stored in the standby chamber 120 is transferred through the transfer chamber 110 into the reaction chamber 100 (S52).

Then, in the same manner as with the second wafer W2, a film containing gallium (Ga) such as a GaN single-crystal film is grown over the AlN film on the fourth wafer W4 (S54). After the film formation, in the same manner as with the second wafer W2, the fourth wafer W4 is transferred to the outside of the reaction chamber 100 (S56).

A stacked film of an AlN film and a GaN film is formed through the above processes on the second, third, and fourth wafers W2, W3, and W4, which are Si wafers.

A deposit containing Ga adhering to the support 12 may cause irregularities or holes on a wafer in subsequent film forming in the reaction chamber 100 due to reaction between Si of the wafer and Ga. This hinders formation of a high-quality film on the wafer.

In the present embodiment, a source gas containing gallium (Ga) is supplied into the reaction chamber to form a film on the first wafer W1, and then an AlN film is formed on the dummy substrate Wd, so as to cover the deposit containing Ga on, for example, the support 12 with the AlN film. This suppresses dispersion of, for example, Ga from the deposit into the atmosphere of the reaction chamber 100 during subsequent film formation.

Thus, in forming the AlN film on the second to fourth wafers W2 to W4, it is obviated that Ga present in the form of a deposit reacts with Si on the wafer surface. Hence, a high-quality film is formed on the second to fourth wafers W2 to W4.

In this state, an AlN film is formed successively on a plurality of wafers, which wafers have a silicon (Si) surface. After that, a GaN film is formed over the AlN film on the same plurality of wafers. Hence, a step of covering the deposit on, for example the support 12 with an AlN film is eliminated, which step may have otherwise had to be performed each time a film containing Ga is formed. Thus, the throughput is improved in forming an AlN film and a GaN film on a plurality of wafers.

Further, according to the present embodiment, the wafers completed with the AlN film formation are not released to the air but are temporarily stored in the standby chamber 120. Hence, the time taken to transfer the wafers in and out of the reaction chamber 100 is cut when forming the GaN film over the AlN film on each wafer.

During a period from the start of formation of an aluminum nitride film on the second wafer W2 to the completion of formation of an aluminum nitride film on the fourth wafer W4, the reaction chamber 100, the transfer chamber 110, and the standby chamber 120 are desirably maintained at a first pressure. During a period from the start of formation of a film containing gallium (Ga) on the second wafer W2 to the completion of formation of a film containing gallium (Ga) on the fourth wafer W4, the reaction chamber 100, the transfer chamber 110, and the standby chamber 120 are desirably maintained at a second pressure that is higher than the first pressure.

Typically, according to the MOCVD method, AlN films are formed at a pressure lower than the pressure for forming GaN films. According to the present embodiment, while an AlN film is being formed successively on a plurality of wafers, the reaction chamber 100, the transfer chamber 110, and the standby chamber 120 are maintained at the first pressure which is a pressure for forming AlN films. Then, while a GaN film is being formed successively on the plurality of wafers, the reaction chamber 100, the transfer chamber 110, and the standby chamber 120 are maintained at the second pressure which is a pressure for forming GaN films and is higher than the first pressure.

Hence, switching of pressures is reduced in number as compared to the case of forming an AlN film and a GaN film successively per wafer. Thus, the throughput is improved in forming AlN films and GaN

It is to be noted that according to the present embodiment, an example is described in which an aluminum nitride (AlN) film is formed as a coating film, but the coating film may be any film besides the AlN film insofar as the film covers the deposit adhering to, for example, the support 12. Any film may be used insofar as the film is formable without positively flowing a gas containing Ga as a process gas during the film formation and also the film does not easily decompose during subsequent formation of an AlN film and a GaN film. For example, a silicon nitride (SiN) may also be adopted.

### Second Embodiment

A vapor phase growth method according to a second embodiment is the same as the method according to the first embodiment except that the deposit is removed, after the first substrate is transferred out of the reaction chamber, by heating the support at a temperature higher than the film forming temperature for forming the film containing gallium (Ga) on the first substrate, instead of forming a coating film. Thus, description of details that overlap those of the first embodiment is not given redundantly.

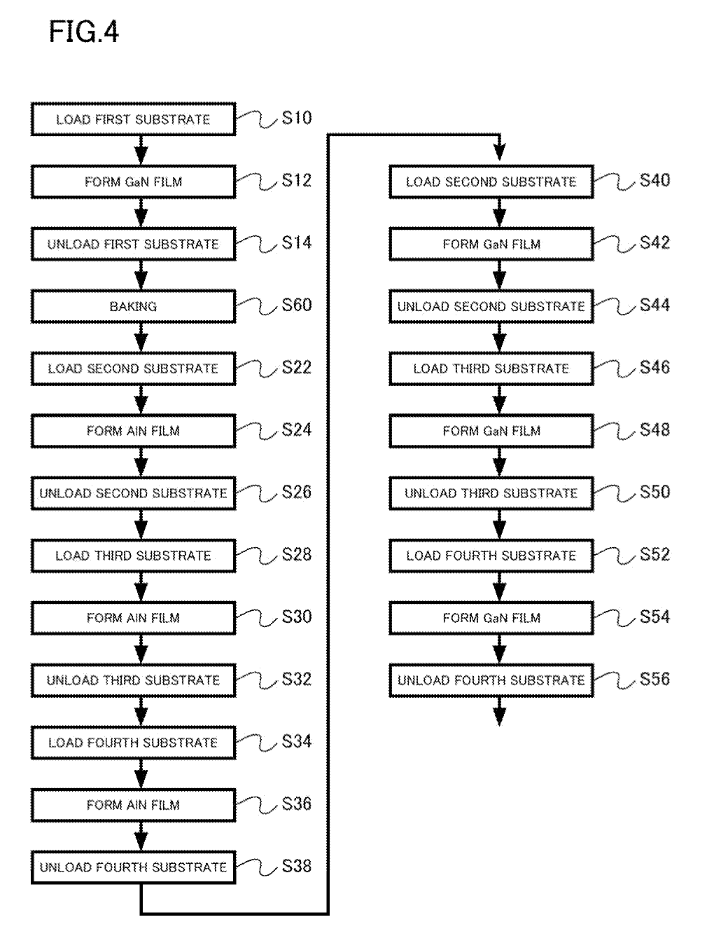

FIG. 4 is a process flow diagram of the vapor phase growth method according to the second embodiment. The vapor phase growth method according to the second embodiment is performed by using the single wafer type epitaxial growth apparatus depicted in FIGS. 1 and 2.

In place of the formation of an AlN film (S16, S18, and S20) on dummy substrate Wd in the process flow of the vapor phase growth method according to the first embodiment depicted in FIG. 3, baking (S60) is performed. Baking (S60) is performed through heat treatment with, for example, hydrogen gas (H₂) being supplied as a baking gas into the reaction chamber 100.

The processes up to the unloading of the first wafer (first substrate) W1 (S14) are the same as those of the first embodiment. After the first wafer W1 is transferred out of the reaction chamber 100, for example, the heating power of the heating portion 16 is increased, so as to raise the temperature of the support 12 to a hydrogen baking temperature, such as a temperature at or above 1100° C. Then, hydrogen gas is supplied from the gas supplier 13 through the shower plate 11 into the reaction chamber 100.

At this point, the support 12 is heated at a temperature higher than the temperature at which the formation of the film containing gallium (Ga) is performed on the first wafer (first substrate) W1. This allows the deposit adhering to the support 12 to be dissolved and removed.

Hydrogen gas (H₂) to be supplied into the reaction chamber 100 may be of 100 volume % or may be gas diluted with inert gas such as nitrogen gas.

After that, the processes as from the transfer of the second wafer (second substrate) W2 into the reaction chamber 100 (S22) are the same as those of the first embodiment.

According to the present embodiment, hydrogen baking is performed, thus allowing the deposit adhering to the support 12 to be removed. Hence, dispersion of, for example, Ga from the deposit into the atmosphere of the reaction chamber 100 is suppressed at later film forming. Hence, a high-quality film is formed on the second to fourth wafers W2 to W4.

The present embodiment is the same as the first embodiment in that the throughput is improved in forming an AlN film and a GaN film on a plurality of wafers.

It is to be noted that the temperature at which hydrogen baking is performed is desirably in a range from 1100° C. to 1250° C., and more desirably, in a range from 1150° C. to 1200° C. This is because when the temperature becomes lower than the above range, enhancement of the effect of removing the deposit adhering to the support 12 becomes hard to achieve. Further, once the temperature becomes higher than the above range, the parts and members inside the reaction chamber may become susceptible to heat degradation.

In the present embodiment, an example is described in which hydrogen gas is used as the baking gas; alternatively, inert gas such as nitrogen gas (N₂) or argon gas (Ar) may be adopted as the baking gas in place of hydrogen gas.

### Third Embodiment

A vapor phase growth method according to a third embodiment is the same as the method according to the first embodiment except that, prior to the formation of the coating film, the support is heated at a temperature higher than the temperature at which the formation of the film containing gallium (Ga) is performed on the first substrate after the first substrate is transferred out of the reaction chamber, so as to remove the deposit. Hence, description of details that overlap those of the first embodiment is not given redundantly. Further, the process of removing the deposit is the same as that of the second embodiment. Hence, the details overlapping those of the second embodiment are not described redundantly either.

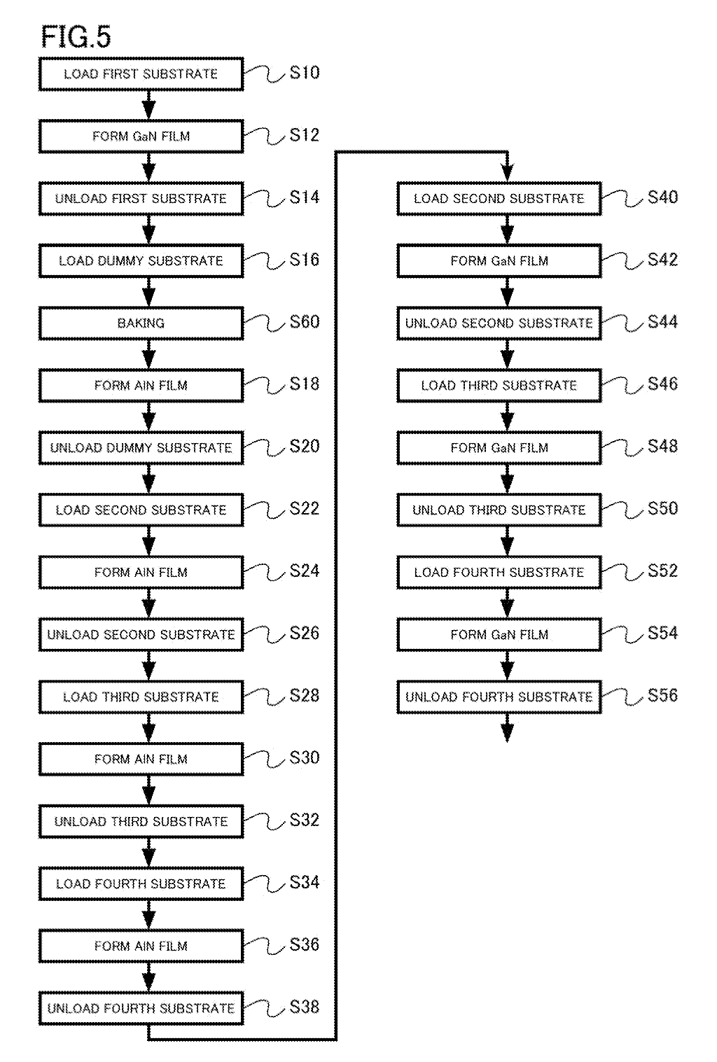

FIG. 5 is a process flow diagram of the vapor phase growth method according to the third embodiment. The vapor phase growth method according to the third embodiment is performed by using the single wafer type epitaxial growth apparatus depicted in FIGS. 1 and 2.

In addition to the process flow of the vapor phase growth method according to the first embodiment depicted in FIG. 3, baking is performed (S60) after the dummy wafer (dummy substrate) Wd is loaded (S16). After that, an AlN film is formed on the dummy wafer Wd (S18). The processes to be performed thereafter are the same as those of the first embodiment.

According to the present embodiment, hydrogen baking is performed, so as to remove the deposit adhering to the support 12 prior to the formation of the coating film. Hence, a higher-quality film is formed on the second to fourth wafers W2 to W4.

The present embodiment is the same as the first embodiment in that the throughput is improved in forming an AlN film and a GaN film on a plurality of wafers.

### Fourth Embodiment

A vapor phase growth apparatus according to a fourth embodiment includes a dedicated reaction chamber for forming aluminum nitride films in addition to the structure of the vapor phase growth apparatus according to the first embodiment. Besides this point, the apparatus is the same as the vapor phase growth apparatus according to the first embodiment. Details overlapping those of the first embodiment are not described redundantly hereinafter.

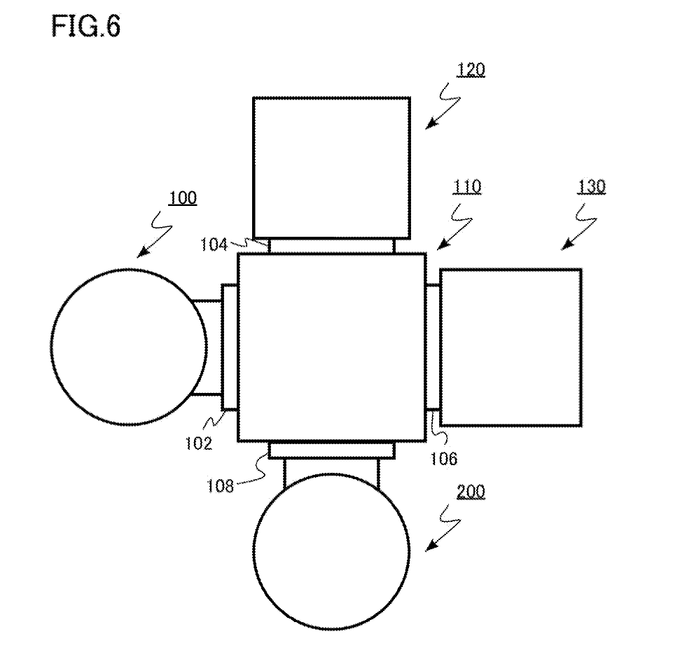

FIG. 6 is a configuration diagram of the vapor phase growth apparatus according to the fourth embodiment. The vapor phase growth apparatus according to the fourth embodiment is a vertical, single wafer type epitaxial growth apparatus for use in the MOCVD method (metalorganic chemical vapor deposition method).

The vapor phase growth apparatus includes a reaction chamber 100, a transfer chamber 110 connected to the reaction chamber 100, and a standby chamber 120 connected to the transfer chamber 110. In addition, the apparatus includes a load lock chamber 130 connected to the transfer chamber 110. Further, the apparatus includes a dedicated reaction chamber 200 for forming aluminum nitride films connected to the transfer chamber 110.

Moreover, a fourth gate valve 108 is further positioned between the transfer chamber 110 and the dedicated reaction chamber 200. The fourth gate valve 108 has a function of separating the atmosphere and pressure between the transfer chamber 110 and the dedicated reaction chamber 200.

According to the present embodiment, formation of AlN films on wafers (substrates) with a silicon (Si) surface is performed in the dedicated reaction chamber 200, and formation of films containing Ga (gallium), for example, GaN films, is performed in the reaction chamber 100.

Hence, Ga in the deposit that has been generated during formation of the film containing Ga (gallium) is fundamentally prevented from reacting with the Si surface in forming an AlN film.

Embodiments of the present invention have been described above with reference to specific examples. The foregoing embodiments are given for an illustrative purpose and not for a restrictive purpose. Further, components of the embodiments may be appropriately combined.

In the embodiments, description is not given for parts and portions which are not directly relevant to the description of the present disclosure, such as the configuration of the apparatus or the manufacturing method; however, a configuration of an apparatus or a manufacturing method may be appropriately selected for use as needed. In addition, the scope of the present disclosure encompasses any vapor phase growth method that includes elements of the present disclosure and that is of an appropriate design choice for those skilled in the art. The scope of the present disclosure is defined by the appended claims and equivalents thereof.

What is claimed is:

1. A vapor phase growth method using a vapor phase growth apparatus including a reaction chamber, a transfer chamber connected to the reaction chamber, and a standby chamber connected to the transfer chamber, the method comprising:
transferring a first substrate into the reaction chamber;
forming a film containing gallium (Ga) on the first substrate being placed on a support inside the reaction chamber;
transferring the first substrate out of the reaction chamber;
covering a deposit with a coating film after the transferring of the first substrate out of the reaction chamber, the deposit adhering to the support;
transferring a second substrate into the reaction chamber after the covering of the deposit with the coating film, the second substrate having a silicon (Si) surface;
forming an aluminum nitride film on the second substrate;
transferring the second substrate from the reaction chamber into the transfer chamber and then into the standby chamber;
transferring a third substrate into the reaction chamber, the third substrate having a silicon (Si) surface;
forming an aluminum nitride film on the third substrate;
transferring the third substrate from the reaction chamber into the transfer chamber and then into the standby chamber;
transferring the second substrate from the standby chamber into the transfer chamber and then into the reaction chamber;
forming a film containing gallium (Ga) on the second substrate;
transferring the second substrate out of the reaction chamber;
transferring the third substrate from the standby chamber into the transfer chamber and then into the reaction chamber;
forming a film containing gallium (Ga) on the third substrate; and
transferring the third substrate out of the reaction chamber.

2. The vapor phase growth method according to claim 1, further comprising transferring a dummy substrate into the reaction chamber and forming an aluminum nitride film to be the coating film on the dummy substrate to cover the deposit, after the transferring of the first substrate out of the reaction chamber.

3. The vapor phase growth method according to claim 2, wherein the reaction chamber, the transfer chamber, and the standby chamber are maintained at a first pressure from start of the forming of the aluminum nitride film on the second substrates to completion of the forming of the aluminum nitride film on the third substrate, and the reaction chamber, the transfer chamber, and the standby chamber are maintained at a second pressure higher than the first pressure from start of the forming of the film containing gallium (Ga) on the second substrate to completion of the forming of the film containing gallium (Ga) on the third substrate.

4. The vapor phase growth method according to claim 1, wherein after the transferring of the first substrate out of the reaction chamber and prior to the covering of the deposit with the coating film, the support is heated at a temperature higher than a film forming temperature to remove the deposit, the film forming temperature being a temperature for forming the film containing gallium (Ga) on the first substrate.

5. The vapor phase growth method according to claim 2, wherein after the transferring of the first substrate out of the reaction chamber and prior to the forming of the aluminum nitride film on the dummy substrate, the support is heated at a temperature higher than a film forming temperature to remove the deposit, the film forming temperature being a temperature for forming the film containing gallium (Ga) on the first substrate.

6. The vapor phase growth method according to claim 1, wherein a film forming temperature for forming the film containing gallium (Ga) on the first substrate is in a range from 1000° C. to 1100° C.

7. The vapor phase growth method according to claim 4, wherein hydrogen gas is supplied in removing the deposit.

8. The vapor phase growth method according to claim 4, wherein the temperature for removing the deposit is in a range from 1100° C. to 1250° C.

9. The vapor phase growth method according to claim 7, wherein the temperature for removing the deposit is in a range from 1100° C. to 1250° C.

10. A vapor phase growth method for using a vapor phase growth apparatus including a reaction chamber, a transfer chamber connected to the reaction chamber, and a standby chamber connected to the transfer chamber, the method comprising:
transferring a first substrate into the reaction chamber;
forming a film containing gallium (Ga) on the first substrate placed on a support inside the reaction chamber;
transferring the first substrate out of the reaction chamber;
removing a deposit after the transferring of the first substrate out of the reaction chamber, the deposit adhering to the support;
transferring a second substrate into the reaction chamber after the removing of the deposit, the second substrate having a silicon (Si) surface;
forming an aluminum nitride film on the second substrate;
transferring the second substrate from the reaction chamber into the transfer chamber and then into the standby chamber;
transferring a third substrate into the reaction chamber, the third substrate having a silicon (Si) surface;
forming an aluminum nitride film on the third substrate;
transferring the third substrate from the reaction chamber into the transfer chamber and then into the standby chamber;
transferring the second substrate from the standby chamber into the transfer chamber and then into the reaction chamber;
forming a film containing gallium (Ga) on the second substrate;
transferring the second substrate out of the reaction chamber;
transferring the third substrate from the standby chamber into the transfer chamber and then into the reaction chamber;
forming a film containing gallium (Ga) on the third substrate; and
transferring the third substrate out of the reaction chamber.

11. The vapor phase growth method according to claim 10, wherein after the transferring of the first substrate out of the reaction chamber, the support is heated at a temperature higher than a film forming temperature to remove the deposit, the film forming temperature being a temperature for forming the film containing gallium (Ga) on the first substrate.

12. The vapor phase growth method according to claim 11, wherein the reaction chamber, the transfer chamber, and the standby chamber are maintained at a first pressure from start of the forming of the aluminum nitride film on the second substrates to completion of the forming of the aluminum nitride film on the third substrate, and the reaction chamber, the transfer chamber, and the standby chamber are maintained at a second pressure higher than the first pressure from start of the forming of the film containing gallium (Ga) on the second substrate to completion of the forming of the film containing gallium (Ga) on the third substrate.

13. The vapor phase growth method according to claim 10, wherein the film forming temperature for forming the film containing gallium (Ga) on the first substrate is in a range from 1000° C. to 1100° C.

14. The vapor phase growth method according to claim 10, wherein hydrogen gas is supplied in removing the deposit.

15. The vapor phase growth method according to claim 10, wherein the temperature for removing the deposit is in a range from 1100° C. to 1250° C.

16. The vapor phase growth method according to claim 14, wherein the temperature for removing the deposit is in a range from 1100° C. to 1250° C.
